(19) United States
(12) Patent Application Publication
(10) Pub. No.: US 2008/0314735 A1
(43) Pub. Date: Dec. 25, 2008

(54) Reactive Multilayer Joining To Control Thermal Stress

(76) Inventors: Timothy P. Weihs, Baltimore, MD (US); Alan Duckham, Baltimore, MD (US); David Lunking, Columbia, MD (US); Jesse Newson, Cockeysville, MD (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 12/143,329

(22) Filed: Jun. 20, 2008

Related U.S. Application Data
(60) Provisional application No. 60/945,813, filed on Jun. 22, 2007.

(51) Int. Cl. C23C 14/34; B32B 15/00

(52) U.S. Cl. 204/192.1; 228/234.3; 428/615; 204/298.12

(57) ABSTRACT

A method for bonding components with a reactive multilayer foil, wherein during bonding, the components are held at a temperature or temperature gradient chosen to reduce thermal stress in the resulting bonded product.

### CROSS-REFERENCE TO RELATED APPLICATIONS

The present application is a non-provisional of, and claims priority from, U.S. Provisional Application Ser. No. 60/945,813 filed on Jun. 22, 2007, which is herein incorporated by reference.

The present application is related to U.S. Pat. No. 6,736,942 issued on May 18, 2004, which is herein incorporated by reference.

### FIELD OF THE INVENTION

This invention relates to the formation of solder or braze bonds: specifically, controlling the stress state of the components being bonded via control of the temperature in the components during bonding.

### BACKGROUND OF THE INVENTION

Bonding with reactive multilayer foil is a new joining technology that enables soldering and brazing without significantly heating the components being bonded. The reactive multilayer foils are magnetron sputtered and consist of thousands of alternating nanoscale layers, such as alternating layers of Ni and Al. The layers react exothermically when atomic diffusion between the layers is initiated by an external energy pulse (FIG. 1), and release a rapid burst of heat in a self-propagating reaction. If the foils are sandwiched between layers of solder or braze alloy, the heat released by the foils can be harnessed to melt these layers (FIG. 2). By controlling the properties of the foils the exact amount of heat released by the foils can be tuned to ensure there is sufficient heat to partially or fully melt the solder or braze layers, but at the same time the bulk of the components will be at or close to room (ambient) temperature. The components therefore do not undergo any significant expansion or contraction during bonding despite differences in coefficient of thermal expansion (CTE). Bonding with reactive multilayer foil is typically a room temperature method that enables high quality metallic bonds between materials with dissimilar CTE's. After bonding at room temperature, no thermal stresses are present in the components at room temperature.

However, bonded components are often used at temperatures above or below room temperature. For example, a target used for physical vapor deposition may have a large temperature gradient from the sputtering surface to the opposite surface, which is generally water-cooled. This target may be generally composed of a plate or tile of a ceramic, metallic, or semi-metallic material bonded along one face to a conductive metal plate, often made of copper or aluminum. During use, the target plate or tile is exposed to a plasma and becomes very hot. The heat travels across the plate or tile, across the bond, into the conductive metal plate, and finally to the back surface of the metal plate which is typically actively cooled by flowing water. The thermal stresses caused by the thermal gradients in the target plate and backing plate as well as between the target plate and backing plate can be large enough to cause the plates to warp, debond, or even crack. In addition, mechanical stresses may contribute to failure in the plates.

In other applications, bonded components with very different CTE's may be used at a uniform elevated temperature. Often, the component with the smaller CTE is also brittle. If the components are bonded using reactive multilayer joining at room (ambient) temperature and thus have no stored thermal stress at room (ambient) temperature, service at elevated temperature creates tension in the component with smaller CTE. This tension can cause cracking in the lower CTE component or delamination of the bond. Even if the components are not brittle, significant warpage can result from stored thermal stresses.

In still other applications, bonded components may be used, stored, or shipped at temperatures below room (ambient) temperature. Bonding at low temperatures can reduce later stress states at low temperatures.

If the difference in CTE between the components is large, e.g. larger than 1 μm/m/K, this effect is more pronounced than if the difference is small.

Examples of items that might be improved by the present invention include large semiconductor devices such as insulated-gate bipolar transistors (IGBT's), which are often bonded to heat sinks and expected to run at high temperatures. Heat shields comprising dissimilar materials, and automotive and aerospace components that are used at elevated temperatures are other examples. Cryogenic and refrigeration system components or components destined for use in outer space might benefit from bonding at temperatures below room (ambient) temperature.

### BRIEF SUMMARY OF THE INVENTION

In accordance with the present disclosure, a method for bonding is provide by which components are bonded using reactive multilayer foil, and wherein the components are held at a temperature or temperature gradient during the bonding process chosen to reduce thermal stress in the bonded product under conditions other than room (ambient) temperature.

### BRIEF DESCRIPTION OF THE SEVERAL VIEWS OF THE DRAWINGS

FIG. 1 is an illustration of reaction propagation in a reactive multilayer foil;

FIG. 2 is a schematic illustration of reactive multilayer bonding;

FIG. 3 illustrates one means of performing reactive multilayer bonding with a temperature gradient across the components;

FIG. 4 is a plot of stress and temperature gradient in a silicon plate bonded to a copper plate vs. distance from the sputtering surface during use; and

FIG. 5 is a plot of elastic strain energy in a bonded structure vs. distance from the bonding temperature.

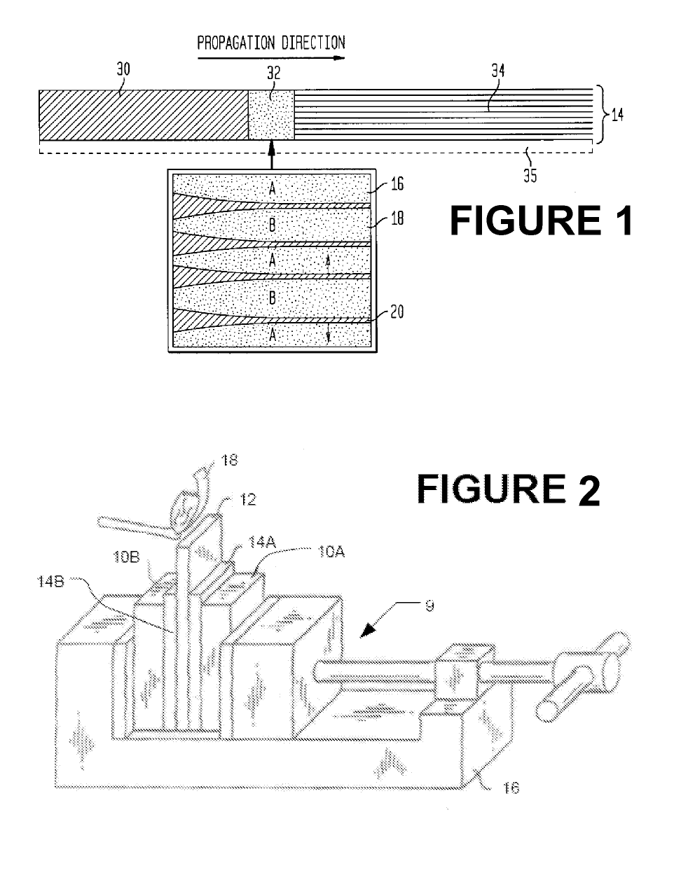

### DETAILED DESCRIPTION

Bonded structures and components may experience a wide but defined range of temperatures during transit, storage, handling, and service in controlled and uncontrolled environmental conditions. The terms “use conditions” or “use temperature range” as used herein are intended to describe the range of temperatures a bonded structure may experience during transit, storage, handling, and service in controlled and uncontrolled environmental conditions.

The bonding method of the present invention results in a bonded structure in which a stress state in the resulting bonded components is achieved which is advantageous at a particular use temperature or range of use temperatures by bonding the components at selected ambient temperatures or within selected temperature gradients.

Turning to FIG. 2, an embodiment of the present disclosure is shown in which at least two components 10 with different coefficients of thermal expansion (CTE) are prepared for bonding together to form a bonded structure by placing a freestanding reactive multilayer foil 12 and an optional fusible material 14 between them, applying pressure e.g. with vise 16 to hold the components 10 against the reactive multilayer foil 12 and the optional fusible material 14, and initiating a reaction in the reactive multilayer foil (shown as the burning match 18 in FIG. 2) to bond the components together. During bonding, the components are held, to within a tolerance, at a selected bonding temperature other than room (ambient) temperature. The selected bonding temperature is chosen based on the desired stresses within the resulting bonded structure. In various embodiments, the bonding temperature is selected to be between room (ambient) temperature and the service (use) temperature of the components in order to reduce the magnitude of the thermal stresses in the bonded components at the service (use) temperature. Alternatively, the selected bonding temperature, whether above or below room (ambient) temperature, is selected to minimize the local thermal stress at a given position in either of the bonded components under a particular set of conditions (service, storage, shipping, etc.) Correspondingly, the bonding temperature may be selected to maintain the maximum stress in the weaker bonded component below a predetermined value, such as the fracture toughness or a fraction thereof, over the use temperature range. In another variation, the bonding temperature is selected to minimize the sum of the elastic strain energy in both bonded components throughout the use temperature range.

Similarly, in a different embodiment, at least two components are bonded using the ignition reaction of the freestanding multilayer reactive foil while being maintained at a temperature which exceeds the highest temperature the bonded components will experience during normal use to ensure that the stress in the component with the smallest CTE is in compression at all times during use.

To illustrate this embodiment, it should be clear that bonding at a temperature above the maximum use temperature of the components will have the effect that the component with the larger CTE (e.g. copper if the components are copper and silicon) will shrink more upon cooling than the second component will, resulting in compressive stress in the second component at the bond line as long as the temperature at the bond line is lower than the temperature was at the bond line during bonding. However, it is often desirable that the compressive stress not be too large, so the bonding temperature should be selected to be as close to the maximum temperature the components will experience as practical, to minimize the compressive stress in the second component.

Alternatively, the two or more components may be bonded using the ignition reaction of the freestanding multilayer reactive foil while being held at a temperature which is within a tolerance of the highest temperature the components will experience during normal use to ensure that the tensile stress in the bonded component with the smallest CTE is minimized at all times during use.

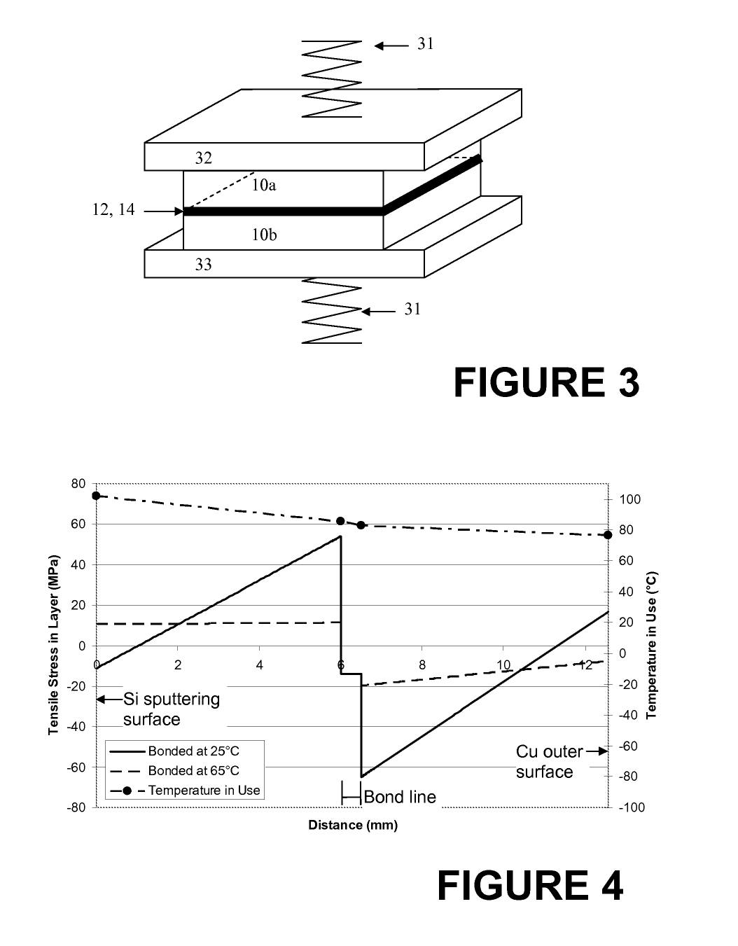

In another embodiment, shown in FIG. 3, at least two components 10 are prepared for bonding by placing a reactive multilayer foil 12 and an optional fusible material 14 between them, applying pressure (e.g. with springs 31) to hold the components 10 against the reactive multilayer foil 12 and the fusible material 14, imposing a temperature gradient across the components, as with a hot plate 32 and a cold plate 33, and initiating a reaction in the reactive multilayer foil to bond the components together. The temperature gradient is selected to create a favorable stress state in the bonded components during service. This is particularly effective when the service conditions include a similar temperature gradient across the components, such as occurs in a target/backing plate assembly during sputter deposition. This method may also be used to minimize elastic strain energy in the bonded components throughout the use temperature range.

In another embodiment, the bonding temperature or temperature gradient is selected to optimize the stresses in the bonded components due not only to the use temperature or temperature gradient, but also due to mechanical forces on the bonded components during use, such as pressure exerted by cooling water against a backing plate in a sputtering target geometry. Another example of a mechanical force which may be experienced by the bonded components (in a target/backing plate assembly) is a bending load exerted by gravity on a large bonded target when held horizontally by the edges during handling. In another example, considerable bending stresses may be put on a bonded target when bolted into a sputtering gun if the backing plate is not flat or the bolts are tightened incorrectly.

To illustrate the concept in general, the following example is provided, and those of ordinary skill in the art will recognize that the present invention is not limited to these specific dimensions or measurements. A silicon target plate is bonded to a copper backing plate. Both plates are 7.5″×7.5″ (19 cm×19 cm) and 0.25″ (6 mm) thick, with a total bond line thickness of 0.022″ (0.57 mm). FIG. 4 illustrates the tensile stress in the plates as a function of the distance from the surface of the silicon target plate for this target in operation under a large thermal load caused by sputtering at the very high power of 40 W/cm² with 20° C. direct cooling water at 31 psig. The calculated temperature profile in the bonded target is also shown in FIG. 4. The stress calculation is based upon an analytical plane strain model and has been verified by finite element modeling. This model assumes no yielding in the solder and the plates. If the two plates are bonded at room (ambient) temperature (25° C., 77° F.) and then experience the above operating conditions, the target experiences a stress state illustrated by the solid line in FIG. 4. The average stress in the silicon is 32 MPa in tension with a maximum at the bond line of 54 MPa in tension, which is probably sufficient to crack the silicon. By comparison, the dashed line in FIG. 4 illustrates the same configuration, but bonded at 65° C. (149° F.). Here, the average stress experienced by the silicon target plate during operation is only 11 MPa in tension, with a maximum of 11.4 MPa in tension, an amount which is unlikely to crack the silicon. Bonding at a lower temperature than 65° C. (149° F.) will result in a tensile stress in the silicon at the bond line larger than 11 MPa, while bonding at a temperature higher than 65° C. (149° F.) will result in increased tensile stress at the surface of the silicon. Either condition may lead to cracking during operation.

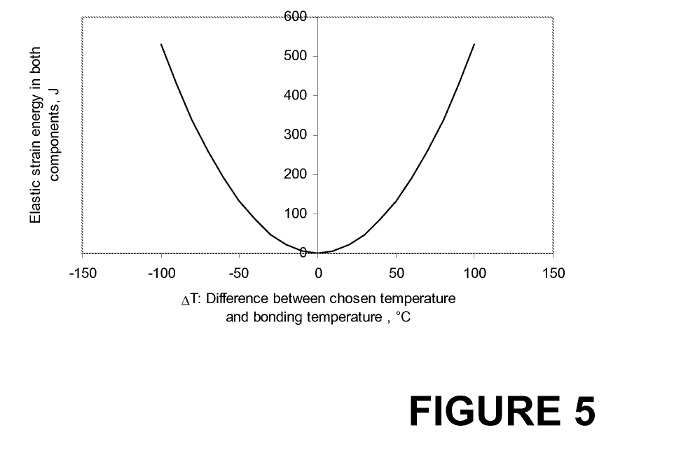

To illustrate one of the embodiments described above, the elastic strain energy was calculated for a silicon target bonded to a copper backing plate. Each plate was 0.125″ (3.13 mm) thick. This calculation was performed using a simplified model for stress that considers only normal stresses in the components generated by CTE mismatch and produces values that are averages for the components. In FIG. 5, the sum of the elastic strain energy in the two components is plotted vs. the difference between a chosen temperature and the bonding temperature (ΔT). As an example, if the bonded components are expected to see temperatures ranging from 0 to 100° C. (32 to 212° F.), the bonding temperature may be selected to minimize the elastic strain energy at all temperatures within the range, by minimizing the area under the curve in FIG. 5. Thus, if the components were bonded at 0° C., the area under the curve from ΔT=0 to ΔT=100° C. would be 17,750 J·° C. However, if the components were bonded at 50° C., the area under the curve from ΔT=−50° C. to ΔT=+50° C. would be 4505 J·° C., much smaller.

The last embodiment may be understood to produce similar average stresses to those produced by the first embodiment, although the bending stresses may differ, but it may be easier to implement in some circumstances. It may be easier to impose a temperature gradient similar to that observed during use than to calculate a single bonding temperature to produce a stress state similar to that which would be observed during use.

Example 1: Silicon sputtering targets were bonded to copper backing plates at two bonding temperatures. Stresses were calculated based on estimated service conditions using the second, simplified, model described above. The targets were installed in a sputtering machine and run until one cracked.

Calculations: A 3″ (7.6 cm) diameter, 0.125″ (3.13 mm) thick silicon target was bonded to a 3″ (7.6 cm) diameter, 0.125″ (3.13 mm) thick copper backing plate. If the target and backing plate are bonded at room (ambient) temperature, the calculated average stress in both the target and backing plate is zero at room (ambient) temperature. If the target is used at 500 W of power to sputter deposit silicon and the backing plate is cooled indirectly, an estimate of the target surface temperature is 57° C. and an estimate of the temperature at the back surface of the backing plate is 40° C. With this temperature gradient, the average temperatures in the target and backing plate are 52° C. and 41° C., respectively. These temperatures are used to calculate normal biaxial stresses in the target and backing plate during service, wherein the silicon target sees 16.5 MPa in tension and the copper backing plate sees 16.5 MPa in compression. If instead the target and backing plate are bonded at an ambient temperature of 50° C., stress is present at room (ambient) temperature (29.2 MPa in compression in the silicon target and in tension in the copper backing plate) and some is present at the service conditions (12.7 MPa in compression in the silicon target and in tension in the copper backing plate). However, in both cases the silicon target is in compression, reducing the chance of cracking when compared with a similar target bonded at room (ambient) temperature.

Room Temperature Bond: A 3″ diameter, 0.125″ thick Si target was bonded to a 3″ diameter 0.125″ thick Cu backing plate at room (ambient) temperature using 60 μm thick reactive multilayer foil. Both components were pre-wet with Sn-3.5Ag solder (0.010″ or 250 μm on each component) on a hot plate prior to bonding. A joining pressure of 0.67 MPa was applied. This target was run in a vacuum chamber in a cathode with indirect cooling in DC power mode. Power was ramped up to 500 W in 20 W increments over a time period of 4 hours. After removal from the chamber it was observed that the Si target had cracked. According to the above calculations, this target was under tension during service. Due to the low fracture toughness of silicon, the target cracked.

Bond at 50° C.: A similar 3″ diameter, 0.125″ thick Si target was bonded to a similar 3″ diameter 0.125″ thick Cu backing plate at 50° C. using 60 μm thick reactive multilayer foil. Both components were pre-wet with Sn-3.5Ag solder (0.010″ or 250 μm on each component) on a hot plate prior to bonding. A joining pressure of 0.67 MPa was applied. This target was run in a vacuum chamber in a cathode with indirect cooling in DC power mode. Power was ramped up to 500 W in 20 W increments over a time period of 4 hours. After removal from the chamber it was noticed that the Si target was intact with no observed cracks, as the silicon target was in compression during use, reducing the likelihood of cracking.

If, during bonding, a temperature gradient is produced across the silicon and copper such that bonding takes place under conditions close to the service conditions, (e.g. 52° C. on average in the silicon, 41° C. on average in the copper in this example) the normal stresses seen by both components during service are zero and the silicon experiences compressive stress when both parts are at room (ambient) temperature (16.5 MPa). A uniform bonding temperature of 39° C. achieves the same result. This bonding temperature creates an average stress at room (ambient) temperature of 16.4 MPa in each component (compression in the silicon).

Example 2: Alumina (Al₂O₃) sputtering target tiles were bonded to copper backing plates at one of two ambient temperatures, namely 25° C. (77° F.) and 75° C. (167° F.). These temperatures were selected based on calculations similar to those performed for the silicon example above. These alumina targets were then thermally stressed in a sputtering gun simulation until failure occurred. The simulation comprised placing the bonded target alumina side down on a hot plate. A cooling plate using room (ambient) temperature water was then placed atop the target. This setup simulated the thermal profile and accompanying stress caused by use in a sputtering system. The temperature of the hot plate was then until failure of the bonded target. Temperature measurements were taken at the surface of the target material in contact with the hot plate during the test.

Room Temperature Bonds: An alumina target 6.57″×3.74″×0.31″ was bonded to a 4″×7″×0.35″ copper backing plate at room (ambient) temperature using 60 μm thick reactive multilayer foil. Both components were pre-wet with 250 μm of Sn-3.5Ag solder prior to bonding and a pressure of 0.5 MPa was applied during bonding. The bonded target was then placed in the sputtering gun simulation and the hot plate temperature was increased until an audible fracture event occurred. The surface temperature of the alumina at fracture averaged 162° C. (324° F.) for five samples.

Bond at 75° C.: Similar alumina targets 6.57″×3.74″×0.31″ were bonded to a 4″×7″×0.35″ copper backing plate at 75° C. (167° F.) using 60 μm thick reactive multilayer foil. Both components were pre-wet with 250 μm of Sn-3.5Ag solder prior to bonding and a joining pressure of 0.5 MPa was applied during bonding. The bonded target was then placed in the sputtering gun simulation and the hot plate temperature was increased until bond failure. In this case, the alumina tiles did not fracture. Instead, at an average surface temperature of 243° C. (469° F.), the Sn-3.5Ag solder which held the tile to the backing plate began to melt and flow out of the bond. At no time during heat up or melting did the alumina tile fracture.

Typically, bonding at temperatures above room (ambient) temperature is advantageous for preventing cracking in sputter targets during service when service conditions are challenging. For instance, if the cooled surface of a copper backing plate reaches a temperature greater than 40° C., the backing plate will exert considerable tensile force on the target plate. This could occur if cooling efficiency is low due to indirect cooling, or warm water temperature, or low water flow rate, among other causes. If the sputtering power is excessively high, for instance greater than 20 W/cm² for silicon, the target plate surface may become excessively hot, heating the backing plate and again causing considerable tensile stress at the bond line. Predicting the stresses under these conditions and bonding at a temperature or temperature gradient above room (ambient) temperature can reduce target cracking, warping, and debonding under these extreme conditions.

As various changes could be made in the above constructions and examples without departing from the scope of the present disclosure, it is intended that all matter contained in the above description, examples, and shown in the accompanying drawings shall be interpreted as illustrative and not in a limiting sense.

1. A method of bonding a first body to a second body comprising the steps of:
disposing, between the first body and the second body, a freestanding reactive multilayer foil;
pressing the bodies together against said freestanding reactive multilayer foil;
bonding said first and second bodies by igniting said freestanding reactive multilayer foil; and
wherein the first and second bodies are held to within a tolerance of a specific temperature during said bonding.

2. The method of claim 1 further comprising the step of disposing at least one layer of fusible material between the first and second bodies before igniting said freestanding reactive multilayer foil.

3. The method of claim 2 wherein the bonded bodies are selected for use at a service temperature, and wherein said bonding specific temperature is above said selected service temperature, but below a melting temperature of said layer of fusible material.

4. The method of claim 1 wherein said bonding specific temperature is chosen to induce a particular stress state in the first and second bodies at a selected temperature.

5. The method of claim 1 wherein said bonding specific temperature is chosen to induce a particular stress state in the first and second bodies in response to a selected temperature gradient.

6. The method of claim 1 wherein the specific temperature is chosen to induce a particular stress state in the two bodies under a particular temperature gradient and mechanical load.

7. The method of claim 1 wherein said specific temperature of the first and second bodies during said bonding differs from the ambient environmental temperature.

8. A method of bonding a first body to a second body comprising the steps of:
disposing a freestanding reactive multilayer foil between the first body and the second body;
pressing the first and second bodies together against said freestanding reactive multilayer foil;
imposing a temperature gradient across the first and second bodies, and freestanding reactive multilayer foil; and
bonding the first and second bodies by igniting said freestanding reactive multilayer foil.

9. The method of claim 8 further including the step of disposing at least one layer of fusible material between the first and second bodies before igniting the freestanding reactive multilayer foil.

10. A bonded structure made by the method of claim 9.

11. A bonded structure made by:
disposing a freestanding reactive multilayer foil between a first body and a second body;
pressing the first and second bodies together against the freestanding reactive multilayer foil;
imposing a temperature gradient across the first and second bodies together with the freestanding reactive multilayer foil; and
bonding the first and second bodies by igniting the freestanding reactive multilayer foil.

12. The bonded structure of claim 11 wherein the bonded structure is a sputter target.

13. A bonded structure made by:
disposing a freestanding reactive multilayer foil between the first body and the second body;
pressing the first and second bodies together against the freestanding reactive multilayer foil; and
bonding the first and second bodies by igniting the freestanding reactive multilayer foil, while maintaining said first body and said second body at a specific temperature.

14. The bonded structure of claim 13 wherein the bonded structure is a sputter target.

15. A bonded structure comprising:
a first body and a second body, with a layer comprising a reacted multilayer foil between disposed there between,
wherein the first body has a CTE that is smaller than a CTE of the second body by at least 1 μm/m/K; and
wherein the stress in the first body is compressive at room (ambient) temperature.

16. The bonded structure of claim 15 wherein the bonded structure is a sputter target.

17. A bonded structure comprising:
a first body and a second body, with a layer comprising a fusible material and reacted multilayer foil disposed there between,
wherein the first body has a CTE that is smaller than a CTE of the second body by at least 1 μm/m/K; and
wherein a magnitude of stress in the bonded bodies is lower at high temperature than at low temperature.

18. The bonded structure of claim 17 wherein the bonded structure is a sputter target.

19. A bonded structure comprising:
a first body and a second body, with a layer comprising a fusible material and a reacted multilayer foil disposed there between,
wherein the first body has a CTE that is smaller than a CTE of the second body by at least 1 μm/m/K; and
wherein a stress in the first body is compressive at all temperatures in a use temperature range of the bonded structure.

20. The bonded structure of claim 19 wherein the bonded structure is a sputter target.

21. A method of vapor deposition onto a substrate, comprising
providing a backing plate and at least one target plate;
disposing at least one layer of a reactive composite material and at least one layer of solder or braze between said backing plate and said target plate;
applying pressure on said layer of reactive composite material through said backing plate and said target plate;
imposing a temperature gradient across said backing plate, said layer of reactive composite material, and said target plate;
bonding said backing plate to said target plate by initiating an exothermic reaction in said layer of reactive composite material;
installing said bonded target and backing plates in a vacuum deposition chamber; and
vapor depositing material from said bonded target plate onto a substrate.

22. A method of vapor deposition onto a substrate comprising:
providing a backing plate and at least one target plate;
holding said backing plate and said target plate at a specific temperature;
disposing at least one layer of a reactive composite material and at least one layer of a solder or braze between said backing plate and said target plate;
applying pressure on said layer of reactive composite material through said backing plate and said target plate;
bonding said backing plate and said target plate by initiating an exothermic reaction in said layer of reactive composite material;
installing said bonded target and backing plates in a vacuum deposition chamber; and
vapor depositing material from said bonded target plate onto the substrate.
